(19) United States
(12) Patent Application Publication
(10) Pub. No.: US 2024/0338589 A1
(43) Pub. Date: Oct. 10, 2024

(54) ELECTRONIC CIRCUIT AND COMPUTING DEVICE

(71) Applicant: KABUSHIKI KAISHA TOSHIBA, Tokyo (JP)

(72) Inventors: HAYATO GOTO, Kawasaki Kanagawa (JP); KENTARO KUBO, Kawasaki Kanagawa (JP)

(73) Assignee: KABUSHIKI KAISHA TOSHIBA, Tokyo (JP)

(21) Appl. No.: 18/424,134

(22) Filed: Jan. 26, 2024

(30) Foreign Application Priority Data
Apr. 6, 2023 (JP) 2023-061890

(51) Int. Cl. G06N 10/40; B82Y 10/00; G06N 10/20; H10N 60/12; H10N 69/00

(52) U.S. Cl. CPC G06N 10/40; B82Y 10/00; H10N 69/00; G06N 10/20; H10N 60/12

(57) ABSTRACT

According to one embodiment, an electronic circuit includes an element section. The element section includes a first coupler, a first resonator, and a first conductive member. The first coupler is configured to be capacitively coupled with a first qubit and a second qubit. The first coupler includes a loop. The first resonator is configured to be inductively coupled with the loop. The first conductive member is configured to be capacitively coupled with the first resonator. An excitation signal for exciting the first resonator is inputted to the first conductive member.

### CROSS-REFERENCE TO RELATED APPLICATIONS

This application is based upon and claims the benefit of priority from Japanese Patent Application No. 2023-061890, filed on Apr. 6, 2023; the entire contents of which are incorporated herein by reference.

### FIELD

Embodiments described herein relate generally to an electronic circuit and computing device.

### BACKGROUND

For example, electronic circuits including multiple nonlinear elements are used in computing devices. Improvements in performance are desired in electronic circuits and computing devices.

### BRIEF DESCRIPTION OF THE DRAWINGS

FIG. 1 is a schematic plan view illustrating an electronic circuit according to a first embodiment;

FIG. 2 is a schematic plan view illustrating a part of the electronic circuit according to the first embodiment;

FIG. 3 is an equivalent circuit illustrating the electronic circuit according to the first embodiment;

FIG. 4 is a graph illustrating the characteristics of the electronic circuit according to the first embodiment;

FIGS. 5A to 5C are schematic diagrams illustrating an electronic circuit according to the first embodiment;

FIGS. 6A to 6C are schematic diagrams illustrating an electronic circuit according to the first embodiment;

FIGS. 7A to 7C are schematic diagrams illustrating an electronic circuit according to the first embodiment;

FIG. 8 is an equivalent circuit illustrating the electronic circuit according to the first embodiment;

FIGS. 9A to 9C are schematic diagrams illustrating an electronic circuit according to the first embodiment; and

FIGS. 10A to 10E are schematic cross-sectional views illustrating a part of the electronic circuit according to the first embodiment.

### DETAILED DESCRIPTION

According to one embodiment, an electronic circuit includes an element section. The element section includes a first coupler, a first resonator, and a first conductive member. The first coupler is configured to be capacitively coupled with a first qubit and a second qubit. The first coupler includes a loop. The first resonator is configured to be inductively coupled with the loop. The first conductive member is configured to be capacitively coupled with the first resonator. An excitation signal for exciting the first resonator is inputted to the first conductive member.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

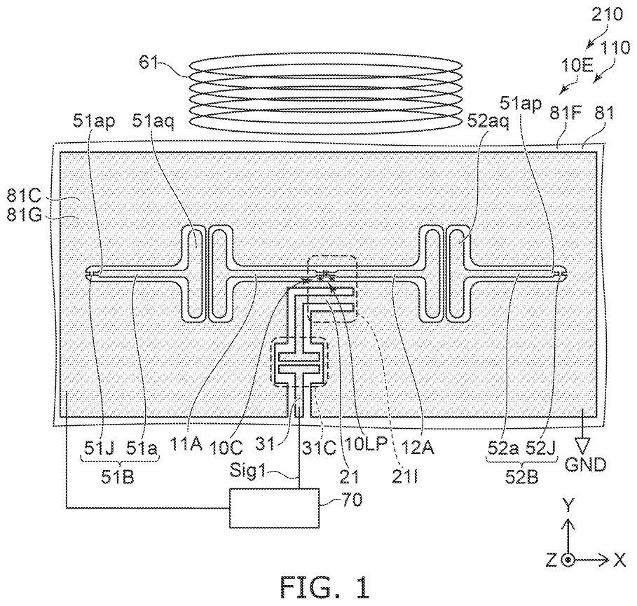

FIG. 1 is a schematic plan view illustrating an electronic circuit according to the first embodiment.

As shown in FIG. 1, an electronic circuit 110 according to the embodiment includes an element section 10E. The element section 10E includes a first coupler 10C, a first resonator 21, and a first conductive member 31. The element section 10E may include a first qubit 51B and a second qubit 52B.

The first coupler 10C is configured to be capacitively coupled with the first qubit 51B and the second qubit 52B. The first coupler 10C includes a loop 10LP.

The first resonator 21 is configured to be inductively coupled to the loop 10LP (inductive coupling 211 illustrated in FIG. 1). The first conductive member 31 is configured to be capacitively coupled to the first resonator 21 (capacitive coupling 31C illustrated in FIG. 1). An excitation signal Sig1 for exciting the first resonator 21 is inputted to the first conductive member 31.

For example, a controller 70 is provided. The excitation signal Sig1 is supplied from the controller 70 to the first conductive member 31.

The electronic circuit 110 may be included in a computing device 210. The computing device 210 includes the electronic circuit 110 according to the embodiment and the controller 70. The computing device 210 including the electronic circuit 110 is configured to execute a computation.

In the electronic circuit 110, the excitation signal Sig1 is supplied to the first resonator 21 by capacitive coupling through the first conductive member 31. Thereby, for example, the first resonator 21 is configured to be resonated by the excitation signal Sig1 of alternating current (high frequency). Due to the amplification effect of the resonator, for example, the power required for gate operation can be reduced. For example, a direct current component signal is substantially not supplied to the first resonator 21. Thereby, mixing of low-frequency noise can be suppressed. For example, the supply path of the excitation signal Sig1 becomes simple. For example, it becomes easy to provide a plurality of element section 10E at a high density. High-density electronic circuits are obtained. According to the embodiment, electronic circuits and computing devices capable of improving performance can be provided.

For example, there is a reference example in which the excitation signal Sig1 is supplied directly to a wiring connected to the ground. In this reference example, the excitation signal Sig1 is supplied to the wiring without passing through the resonator. In this reference example, since a large current is required for the gate operation, the power required for the gate operation is large. In the reference example, low frequency noise is likely to be mixed. Since wiring that can be inductively coupled to the loop 10LP is electrically connected directly to the controller 70, wiring becomes complicate. For example, it is difficult to provide a plurality of element sections 10E at a high density.

On the other hand, it is easy in the embodiment. The excitation signal Sig1 is supplied to the first resonator 21 by capacitive coupling through the first conductive member 31. The first conductive member 31 can be spatially separated from the first resonator 21. Thereby, the degree of freedom of design of the first conductive member 31 increases. A plurality of element sections 10E of high-density can easily be obtained. As described below, a three-dimensional configuration can be easily applied.

As shown in FIG. 1, in this example, the electronic circuit 110 may include a first base 81. The first base 81 includes a first face 81F. A conductive layer 81C is provided on the first face 81F. For example, the element section 10E may be formed by the conductive layer 81C being patterned.

A direction along the first face 81F is defined as an X-axis direction. A direction along the first face 81F and perpendicular to the X-axis direction is defined as a Y-axis direction. A direction perpendicular to the X-axis direction and the Y-axis direction is defined as a Z-axis direction. The first face 81F is along the X-Y plane. The conductive layer 81C is a layer extending along the X-Y plane.

As shown in FIG. 1, the first qubit 51B may include a first bit Josephson junction 51J and a first bit conductive portion 51a. A part 51ap of first bit conductive portion 51a is connected to first bit Josephson junction 51J. Another part 51aq of the first bit conductive portion 51a is configured to be capacitively coupled to the first coupler 10C.

The second qubit 52B may include a second bit Josephson junction 52J and a second bit conductive portion 52a. A part 52ap of the second bit conductive portion 52a is connected to the second bit Josephson junction 52J. Another part 52aq of the second bit conductive portion 52a is configured to be capacitively coupled to the first coupler 10C.

In this example, a first connecting conductive portion 11A and a second connecting conductive portion 12A are provided. The other part 51aq of the first bit conductive portion 51a is configured to be capacitively coupled to the first coupler 10C via the first connecting conductive portion 11A. The other part 52aq of the second bit conductive portion 52a is configured to be capacitively coupled to the first coupler 10C via the second 15 connecting conductive portion 12A.

As shown in FIG. 1, the electronic circuit 110 may further include a magnetic flux controller 61. The magnetic flux controller 61 may control the flux in a space in the loop 10LP. The magnetic flux controller 61 may be included in the computing device 210. For example, a current supplied from the controller 70 to the magnetic flux controller 61 includes a direct current component. The magnetic field generated by the current passes through the space in the loop 10LP. The current can control the magnetic flux in the space in the loop 10LP. The current may be supplied to the magnetic flux controller 61 from an electronic circuit (such as a current source) different from the controller 70.

In the embodiment, a plurality of element sections 10E may be provided. At least a part of the plurality of element sections 10E is provided in the first base 81. The magnetic flux controller 61 may apply a magnetic field to the plurality of element sections 10E at once. For example, the magnetic flux controller 61 may control the magnetic flux in the space in the loop 10LP included in each of the plurality of element sections 10E. The configuration becomes simpler.

As shown in FIG. 1, the electronic circuit 110 may include a reference potential layer 81G. The reference potential layer 81G is formed by a part of the conductive layer 81C. The reference potential layer 81G is set to a ground potential GND, for example. For example, the reference potential layer 81G is provided around at least a part of the first coupler 10C, the first resonator 21, the first conductive member 31, the first qubit 51B, and the second qubit 52B.

An example of the first coupler 10C will be described below.

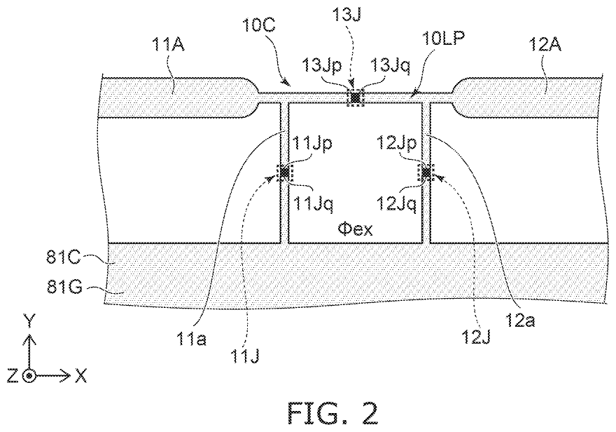

FIG. 2 is a schematic plan view illustrating a part of the electronic circuit according to the first embodiment.

As shown in FIG. 2, the loop 10LP of the first coupler 10C includes a first coupler Josephson junction 11J, a second coupler Josephson junction 12J, a third coupler Josephson junction 13J, a first coupler conductive portion 11a, and a second coupler conductive portion 12a.

The first coupler conductive portion 11a is provided between a part 11Jp of the first coupler Josephson junction 11J and a part 13Jp of the third coupler Josephson junction 13J. The first coupler conductive portion 11a is connected to the part 11Jp of the first coupler Josephson junction 11J and the part 13Jp of the third coupler Josephson junction 13J. The connection may be an electrical connection.

The second coupler conductive portion 12a is provided between a part 12Jp of the second coupler Josephson junction 12J and the other part 13Jq of the third coupler Josephson junction 13J. The second coupler conductive portion 12a is connected to the part 12Jp of the second coupler Josephson junction 12J and the other part 13Jq of the third coupler Josephson junction 13J. The connection may be an electrical connection.

The other part 11Jq of the first coupler Josephson junction 11J is connected to the other part 12Jq of the second coupler Josephson junction 12J. In this example, the other part 11Jq is electrically connected to the other part 12Jq by the reference potential layer 81G.

The first coupler conductive portion 11a is configured to be capacitively coupled to the first qubit 51B. The first coupler conductive portion 11a is configured to be capacitively coupled to the first qubit 51B via the first connecting conductive portion 11A.

The second coupler conductive portion 12a is configured to be capacitively coupled to the second qubit 52B. The second coupler conductive portion 12a is configured to be capacitively coupled to the second qubit 52B via the second connecting conductive portion 12A.

As shown in FIGS. 1 and 2, the other part 51aq of the first bit conductive portion 51a is configured to be capacitively coupled to the first coupler conductive portion 11a via the first connecting conductive portion 11A. The other part 52aq of the second bit conductive portion 52a is configured to be capacitively coupled to the second coupler conductive portion 12a via the second connecting conductive portion 12A.

The magnetic flux ϕex in the space inside the loop 10LP is controlled by the magnetic flux controller 61 (see FIG. 1).

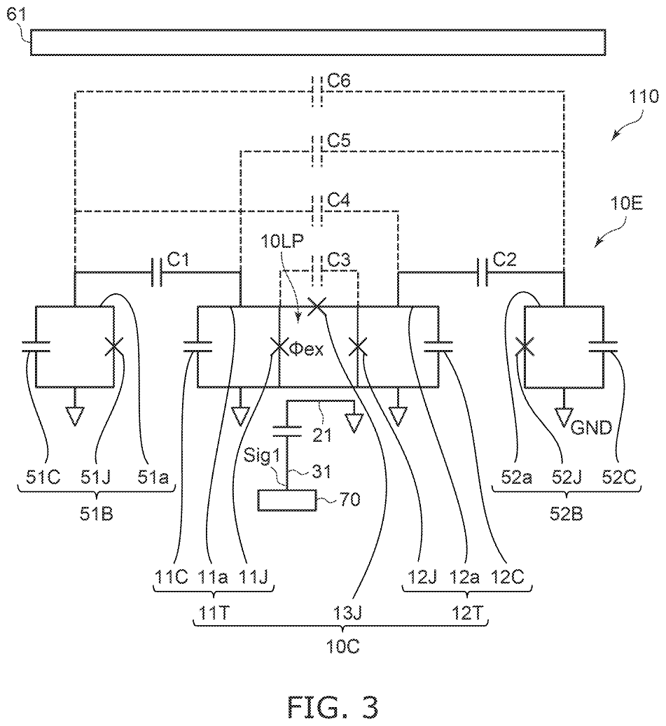

FIG. 3 is an equivalent circuit illustrating the electronic circuit according to the first embodiment.

As shown in FIG. 3, the first qubit 51B may include a first bit capacitor 51C in addition to the first bit Josephson junction 51J and the first bit conductive portion 51a. The first bit capacitor 51C is connected in parallel to the first bit Josephson junction 51J.

The second qubit 52B may include a second bit capacitor 52C in addition to the second bit Josephson junction 52J and the second bit conductive portion 52a. The second bit capacitor 52C is connected in parallel to the second bit Josephson junction 52J.

The first coupler capacitor 11C may be provided in parallel with the first coupler Josephson junction 11J. The first coupler Josephson junction 11J, the first coupler conductive portion 11a, and the first coupler capacitor 11C become the first coupler resonator 11T. The first coupler resonator 11T is, for example, one transmon resonator.

The second coupler capacitor 12C connected in parallel to the second coupler Josephson junction 12J may be provided. The second coupler Josephson junction 12J, the second coupler conductive portion 12a, and the second coupler capacitor 12C become the second coupler resonator 12T. The second coupler resonator 12T is, for example, one transmon resonator. The first coupler 10C is, for example, a double transmon coupler. The first coupler 10C is, for example, a tunable coupler.

As shown in FIG. 3, the first qubit 51B and the first coupler conductive portion 11a are capacitively coupled by the first capacitor C1. The second qubit 52B and the second coupler conductive portion 12a are capacitively coupled by the second capacitor C2.

A third capacitor C3 parallel to the third coupler Josephson junction 13J may be provided. A fourth capacitor C4 may be provided between the first bit conductive portion 51a and the second coupler conductive portion 12a. A fifth capacitor C5 may be provided between the second bit conductive portion 52a and the first coupler conductive portion 11a. A sixth capacitor C6 may be provided between the first bit conductive portion 51a and the second bit conductive portion 52a.

As shown in FIG. 3, the first resonator 21 is provided near the loop 10LP of the first coupler 10C. The first conductive member 31 capacitively coupled to the first resonator 21 is provided. The controller 70 supplies an excitation signal Sig1 to the first conductive member 31.

In the example of FIG. 3, one end of the first resonator 21 is set to a ground potential GND. One end of the first resonator 21 may be floating.

An example of the operation of the electronic circuit 110 (and the computing device 210) will be described below.

The first qubit 51B has a first bit frequency fb1. The second qubit 52B has a second bit frequency fb2.

The first qubit 51B has a first state and a second state different from the first state. The first bit frequency fb1 is a frequency corresponding to a difference between a first energy in the first state and a second energy in the second state. The second qubit 52B has a third state and a fourth state different from the third state. The second bit frequency fb2 is a frequency corresponding to a difference between a third energy in the third state and a fourth energy in the fourth state.

In the embodiment, the resonance characteristics of the first resonator 21 may be determined according to the first bit frequency fb1 and the second bit frequency fb2.

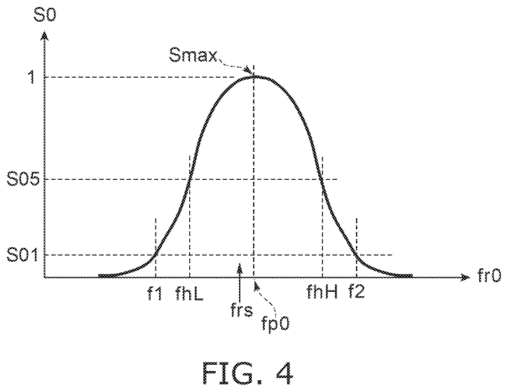

FIG. 4 is a graph illustrating the characteristics of the electronic circuit according to the first embodiment.

FIG. 4 illustrates the resonance characteristics of the first resonator 21. The horizontal axis of FIG. 4 has a frequency fr0. The vertical axis has an intensity S0. As shown in FIG. 4, the intensity S0 of the resonance characteristic has a maximum value Smax at a frequency fp0. When the frequency fr0 is lower than the frequency fp0, the intensity S0 decreases as the frequency fr0 decreases. When the frequency fr0 is higher than the frequency fp0, the intensity S0 decreases as the frequency fr0 increases.

As shown in FIG. 4, the resonance characteristic of the first resonator 21 includes a first frequency f1 and a second frequency f2 higher than the first frequency f1. At the first frequency f1, the intensity S0 of the resonance characteristic is 0.1 times the maximum value Smax of the resonance characteristic. At the second frequency f2, the intensity S0 of the resonance characteristic is 0.1 times the maximum value Smax.

Such resonance characteristics correspond to the first bit frequency fb1 and the second bit frequency fb2. As shown in FIG. 4, a sum of the first bit frequency fb1 and the second bit frequency fb2 is defined as ae sum frequency frs. The sum frequency frs is between the first frequency f1 and the second frequency f2. That is, the first frequency f1 is lower than the sum (sum frequency frs) of the first bit frequency fb1 and the second bit frequency fb2. The second frequency f2 is higher than the sum (sum frequency frs).

Thus, for example, resonance in the first resonator 21 can be effectively applied to the first coupler 10C. For example, the first qubit 51B and the second qubit 52B can be effectively controlled.

For example, in the first qubit 51B and the second qubit 52B, the oscillation between a |00> state and a |11> state can be effectively achieved. For example, the two-qubit gate in two qubits can be performed. For example, the two-qubit gates can be performed with 99.99% accuracy in 30 ns of time.

As shown in FIG. 4, the resonance characteristic of the first resonator 21 has a full width at half maximum. A lower frequency fhL of the full width at half maximum is lower than a sum (sum frequency frs) of the first bit frequency fb1 and the second bit frequency fb2. The upper frequency fhH of the full width at half maximum is higher than the sum (sum frequency frs). For example, the sum frequency frs is set between the lower frequency fhL of the full width at half maximum and the upper frequency fhH of the full width at half maximum. At the lower frequency fhL and the upper frequency fhH, the intensity S0 of the resonance characteristic becomes 0.5 times the maximum value Smax. The upper frequency fhH is higher than the lower frequency fhL.

For example, the frequency fp0 at which the intensity S0 is maximum may be substantially the same as the sum frequency frs.

For example, the excitation signal Sig1 having a frequency compatible with the resonance characteristics of the first resonator 21 is supplied from the controller 70 to the first conductive member 31. The first resonator 21 can be resonated with high efficiency.

For example, the excitation signal Sig1 includes pulses of a first bit frequency fb1 of the first qubit 51B, a second bit frequency fb2 of the second qubit 52B, and a sum frequency (sum frequency frs).

For example, by supplying the excitation signal Sig1 (for example, a pulse) to the first conductive member 31, the controller 70 is configured to execute the two-qubit gate on the first qubit 51B and the second qubit 52B. The frequency of the excitation signal Sig1 is between the first frequency f1 and the second frequency f2. The frequency of the excitation signal Sig1 is between the lower frequency fhL and the upper frequency fhH.

For example, a resonance frequency of the first coupler resonator 11T including the first coupler Josephson junction 11J and the first coupler conductive portion 11a is defined as a first coupler resonance frequency. The first coupler resonance frequency is higher than the first bit frequency fb1, higher than the second bit frequency fb2, and lower than the sum frequency frs. A resonance frequency of the second coupler resonator 12T including the second coupler Josephson junction 12J and the second coupler conductive portion 12a is defined as a second coupler resonance frequency. The second coupler resonance frequency is higher than the first bit frequency fb1, higher than the second bit frequency fb2, and lower than the sum frequency frs.

In one example, the first bit frequency fb1 is, for example, 5.0 GHz. The second bit frequency fb2 is, for example, 5.3 GHZ. The sum frequency frs is, for example, 10.3 GHZ. The first coupler resonance frequency of the first coupler resonator 11T is, for example, 7.0 GHZ. The second coupler resonance frequency of the second coupler resonator 12T is, for example, 7.0 GHZ.

Hereinafter, some examples of the configuration of the element section 10E will be described.

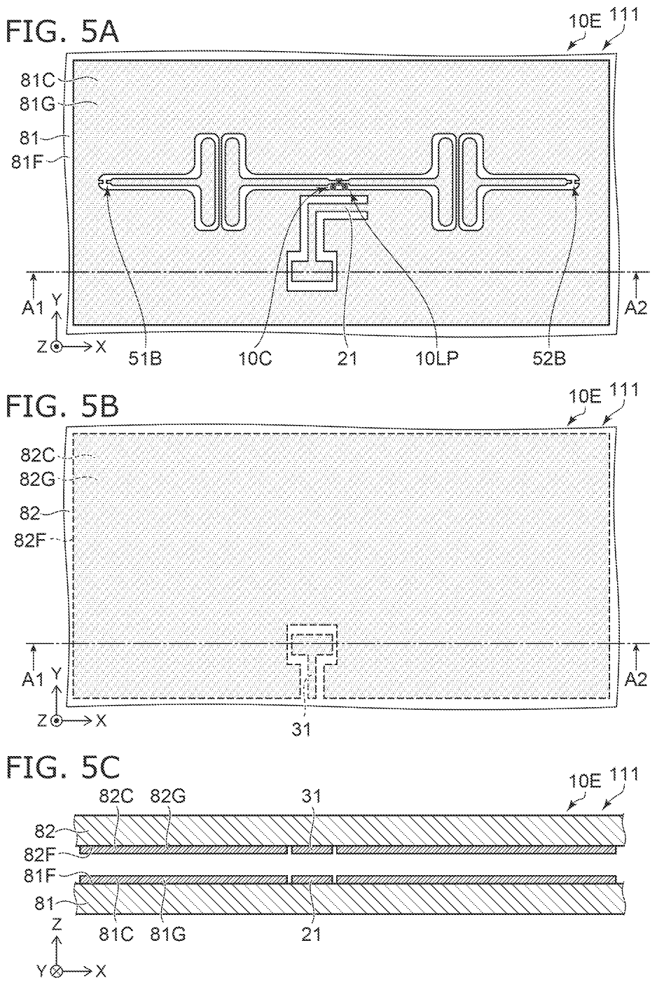

FIGS. 5A to 5C are schematic diagrams illustrating an electronic circuit according to the first embodiment.

FIGS. 5A and 5B are plan views. FIG. 5C is a cross-sectional view taken along the line A1-A2 of FIGS. 5A and 5B.

As shown in FIG. 5A, an electronic circuit 111 according to the embodiment includes the first base 81. As shown in FIG. 5B, the electronic circuit 111 includes a second base 82. As shown in FIG. 5C, the first base 81 and the second base 82 are mutually stacked in the Z-axis direction.

As shown in FIGS. 5A and 5C, the first base 81 includes the first face 81F. As shown in FIGS. 5B and 5C, the second base 82 includes a second face 82F. A direction from the first base 81 to the second base 82 crosses the first face 81F and the second face 82F.

As shown in FIG. 5C, at least a part of the second face 82F faces at least a part of the first face 81F. In the electronic circuit 111, the first coupler 10C and the first resonator 21 are provided at the first face 81F. The first conductive member 31 is provided at the second face 82F. At least a part of the first resonator 21 (and/or the conductive film connected to the first resonator 21) faces at least a part of the first conductive member 31 (and/or the conductive film connected to the first conductive member 31). The first conductive member 31 is capacitively coupled to the first resonator 21.

As shown in FIG. 5B, a conductive layer 82C is provided at the second face 82F. A part of the conductive layer 82C becomes the first conductive member 31. A part of the conductive layer 82C may become a reference potential layer 82G. The reference potential layer 82G is set to a ground potential GND, for example. The reference potential layer 82G is provided around the first conductive member 31.

In the electronic circuit 111, a part of the element section 10E is provided in the first base 81, and another part of the element section 10E is provided in the second base 82. The configuration becomes simple. High integration is easily obtained.

In the electronic circuit 111, a part of the first resonator 21 is capacitively coupled to the first conductive member 31. Another part of the first resonator 21 is connected to the reference potential layer 81G.

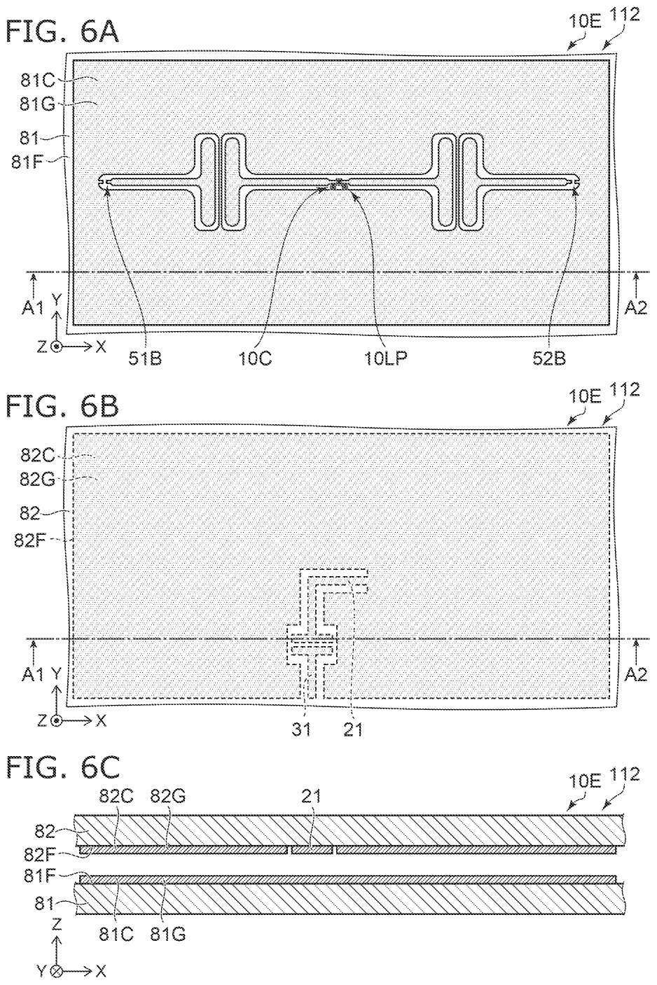

FIGS. 6A to 6C are schematic diagrams illustrating an electronic circuit according to the first embodiment.

FIGS. 6A and 6B are plan views. FIG. 6C is a cross-sectional view taken along the line A1-A2 of FIGS. 6A and 6B.

As shown in FIGS. 6A and 6B, an electronic circuit 112 according to the embodiment includes the first base 81 and the second base 82. As shown in FIG. 6C, at least a part of the second face 82F faces at least a part of the first face 81F. The first coupler 10C is provided at the first face 81F. The first resonator 21 and the first conductive member 31 are provided at the second face 82F. The electronic circuit 112 has a simple configuration as well. High integration is easily obtained.

In the electronic circuit 112, a part of the first resonator 21 is capacitively coupled to the first conductive member 31. Another part of the first resonator 21 is connected to the reference potential layer 82G.

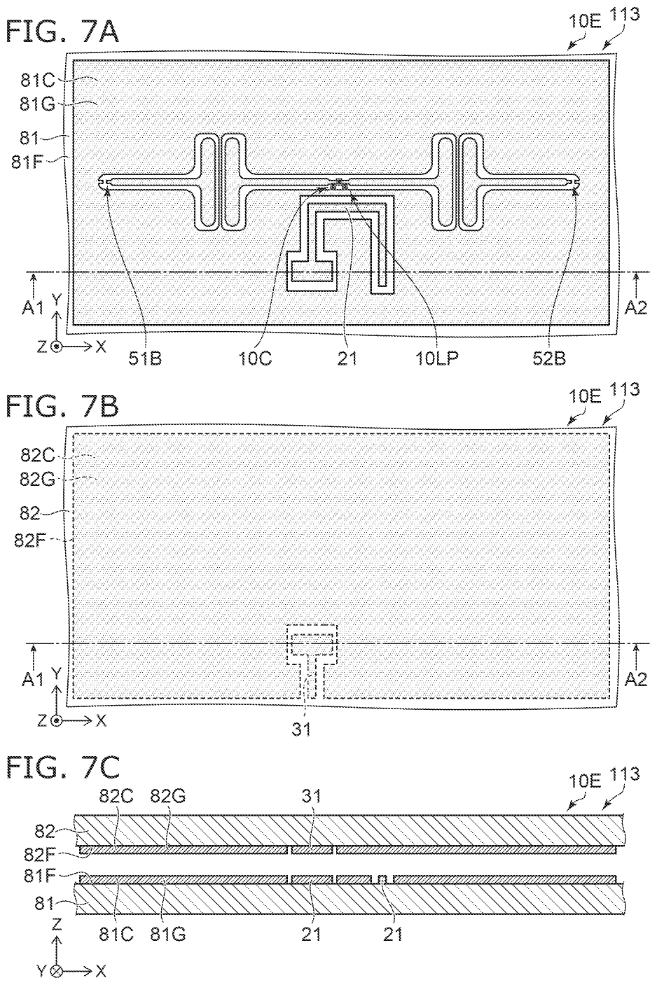

FIGS. 7A to 7C are schematic diagrams illustrating an electronic circuit according to the first embodiment.

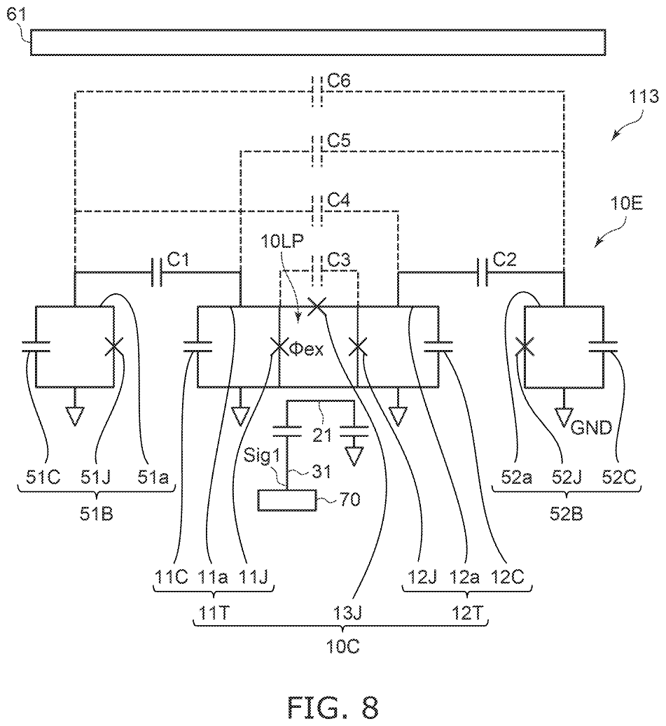

FIG. 8 is an equivalent circuit illustrating the electronic circuit according to the first embodiment.

FIGS. 7A and 7B are plan views. FIG. 7C is a cross-sectional view taken along the line A1-A2 of FIGS. 7A and 7B. As shown in FIGS. 7A and 7B, an electronic circuit 113 according to the embodiment includes the first base 81 and the second base 82. The first coupler 10C and the first resonator 21 are provided at the first face 81F. The first conductive member 31 is provided at the second face 82F. In the electronic circuit 113, the first resonator 21 is floating. As shown in FIG. 8, in the electronic circuit 113, the first resonator 21 may be capacitively coupled to the reference potential layer 81G.

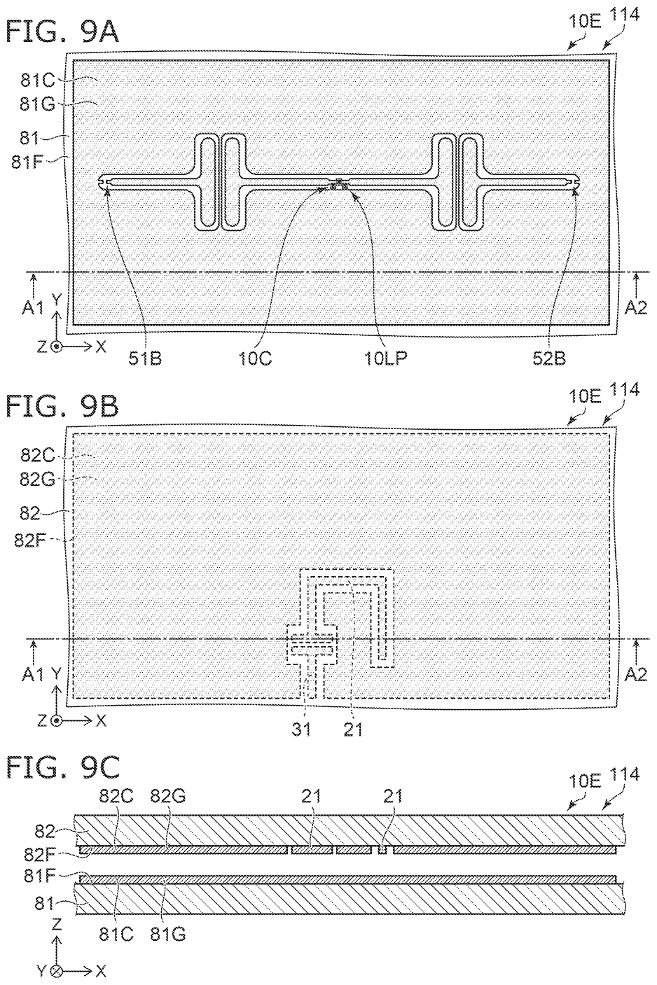

FIGS. 9A to 9C are schematic diagrams illustrating an electronic circuit according to the first embodiment.

FIGS. 9A and 9B are plan views. FIG. 9C is a cross-sectional view taken along the line A1-A2 of FIGS. 9A and 9B. As shown in FIGS. 9A and 9B, an electronic circuit 114 according to the embodiment includes the first base 81 and the second base 82. The first coupler 10C is provided at the first face 81F. The first resonator 21 and the first conductive member 31 are provided at the second face 82F. In the electronic circuit 114, the first resonator 21 is floating. As in the electronic circuit 113, in the electronic circuit 114, the first resonator 21 may be capacitively coupled to the reference potential layer 81G (see FIG. 8).

In the electronic circuits 111-114, at least a part of the first resonator 21 may not overlap the loop 10LP in the direction from the first base 81 to the second base 82 (Z-axis direction). Inductive coupling is effectively obtained.

In the electronic circuits 110-114 according to the embodiment, the first qubit 51B and the second qubit 52B may be provided at the first face 81F.

In the electronic circuits 111-114, the magnetic flux controller 61 may be provided in addition to the element section 10E. In the above drawings of the electronic circuits 111-114, the magnetic flux controller 61 is omitted.

An example of the Josephson junction will be described below.

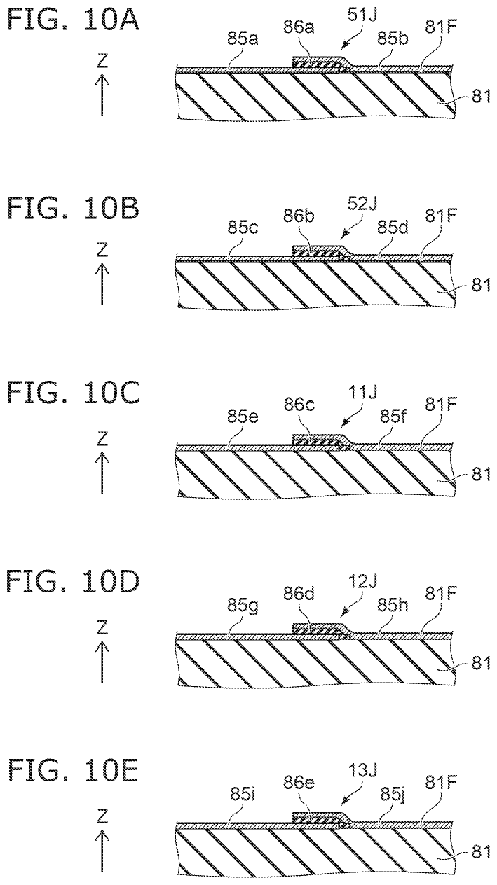

FIGS. 10A to 10E are schematic cross-sectional views illustrating a part of the electronic circuit according to the first embodiment.

As shown in FIG. 10A, in the first bit Josephson junction 51J, a conductive film 85a and a conductive film 85b are provided on the first face 81F of the first base 81. An insulating film 86a is provided between a part of the conductive film 85a and a part of the conductive film 85b.

As shown in FIG. 10B, in the second bit Josephson junction 52J, a conductive film 85c and a conductive film 85d are provided on the first face 81F of the first base 81. An insulating film 86b is provided between a part of the conductive film 85c and a part of the conductive film 85d.

As shown in FIG. 10C, in the first coupler Josephson junction 11J, a conductive film 85e and a conductive film 85f are provided on the first face 81F of the first base 81. An insulating film 86c is provided between a part of the conductive film 85e and a part of the conductive film 85f.

As shown in FIG. 10D, in the second coupler Josephson junction 12J, a conductive film 85g and a conductive film 85h are provided on the first face 81F of the first base 81. An insulating film 86d is provided between a part of the conductive film 85g and a part of the conductive film 85h.

As shown in FIG. 10E, in the third coupler Josephson junction 13J, a conductive film 85i and a conductive film 85j are provided onto the first face 81F of the first base 81. An insulating film 86e is provided between a part of the conductive film 85i and a part of the conductive film 85j.

### Second Embodiment

The second embodiment relates to the computing device 210 (see FIG. 1, etc.). The computing device 210 includes an electronic circuit according to the first embodiment (e.g., electronic circuits 110-114 and variations thereof) and the controller 70. The controller 70 is configured to supply the excitation signal Sig1 to the first conductive member 31. For example, a highly integrated computing device can be provided.

In the computing device 210, for example, the controller 70 is configured to execute two-qubit gate on the first qubit 51B and the second qubit 52B by supplying the excitation signal Sig1 to the first conductive member 31.

The embodiments may include the following configurations (e.g., technical proposals):

### (Configuration 1)

An electronic circuit, comprising:
an element section, including
   a first coupler configured to be capacitively coupled with a first qubit and a second qubit, the first coupler including a loop,
   a first resonator configured to be inductively coupled with the loop; and
   a first conductive member configured to be capacitively coupled with the first resonator, an excitation signal for exciting the first resonator being inputted to the first conductive member.

### (Configuration 2)

The electronic circuit according to Configuration 1, wherein
the first qubit has a first bit frequency,
the second qubit has a second bit frequency,
a resonance characteristic of the first resonator includes a first frequency and a second frequency higher than the first frequency,
at the first frequency, an intensity of the resonance characteristic is 0.1 times a maximum value of the resonance characteristic,
at the second frequency, the intensity of the resonance characteristic is 0.1 times the maximum value,
the first frequency is lower than a sum of the first bit frequency and the second bit frequency, and
the second frequency is higher than the sum.

### (Configuration 3)

The electronic circuit according to Configuration 1, wherein
the first qubit has a first bit frequency,
the second qubit has a second bit frequency,
a lower frequency of a full width at half maximum of a resonance characteristic of the first resonator is lower than a sum of the first bit frequency and the second bit frequency, and
an upper frequency of the full width at half maximum is higher than the sum.

### (Configuration 4)

The electronic circuit according to Configuration 2 or 3, wherein
the first qubit has a first state and a second state different from the first state,
the first bit frequency is a frequency corresponding to a difference between a first energy in the first state and a second energy in the second state,
the second qubit has a third state and a fourth state different from the third state, and
the second bit frequency is a frequency corresponding to a difference between a third energy in the third state and a fourth energy in the fourth state.

### (Configuration 5)

An electronic circuit according to any one of Configurations 1-4, further comprising:
a first base including a first face; and
a second base including a second face,
at least a part of the second face facing at least a part of the first face,
the first coupler and the first resonator being provided at the first face,
the first conductive member being provided at the second face.

### (Configuration 6)

The electronic circuit according to any one of Configurations 1-4, further comprising:
a first base including a first face; and
a second base including a second face,
at least a part of the second face facing at least a part of the first face,
the first coupler being provided at the first face, and
the first resonator and the first conductive member being provided at the second face.

### (Configuration 7)

The electronic circuit according to Configuration 5 or 6, wherein
at least a part of the first resonator does not overlap the loop in a direction from the first base to the second base.

### (Configuration 8)

The electronic circuit according to any one of Configurations 1-7, wherein
the loop includes
   a first coupler Josephson junction,
   a second coupler Josephson junction,
   a third coupler Josephson junction,
   a first coupler conductive portion between a part of the first coupler Josephson junction and a part of the third coupler Josephson junction, and
   a second coupler conductive portion between a part of the second coupler Josephson junction and another part of the third coupler Josephson junction,
another portion of the first coupler Josephson junction is connected to another part of the second coupler Josephson junction,
the first coupler conductive portion is configured to be capacitively coupled with the first qubit, and
the second coupler conductive portion is configured to be capacitively coupled with the second qubit.

### (Configuration 9)

The electronic circuit according to Configuration 8, wherein
the element section further includes the first qubit and the second qubit,
the first qubit includes a first bit Josephson junction and a first bit conductive portion,
a part of the first bit conductive portion is connected to the first bit Josephson junction,
another part of the first bit conductive portion is capacitively coupled to the first coupler conductive portion,
the second qubit includes a second bit Josephson junction and a second bit conductive portion,
a part of the second bit conductive portion is connected to the second bit Josephson junction, and
another part of the second bit conductive portion is capacitively coupled to the second coupler conductive portion.

### (Configuration 10)

The electronic circuit according to Configuration 2 or 3, wherein
the loop includes
   a first coupler Josephson junction,
   a second coupler Josephson junction,
   a third coupler Josephson junction,
   a first coupler conductive portion between a part of the first coupler Josephson junction and a part of the third coupler Josephson junction, and
   a second coupler conductive portion between a part of the second coupler Josephson junction and another portion of the third coupler Josephson junction,
another part of the first coupler Josephson junction is connected to another part of the second coupler Josephson junction,
the first coupler conductive portion is capacitively coupled with the first qubit,
the second coupler conductive portion is capacitively coupled with the second qubit,
a first coupler resonance frequency of the first coupler resonator including the first coupler Josephson junction and the first coupler conductive portion is higher than the first bit frequency, higher than the second bit frequency, and lower than the sum, and
a second coupler resonance frequency of the second coupler resonator including the second coupler Josephson junction and the second coupler conductive portion is higher than the first bit frequency, higher than the second bit frequency, and lower than the sum.

### (Configuration 11)

The electronic circuit according to any one of Configuration 1-9, further comprising
a magnetic flux controller configured to control a magnetic flux in a space in the loop.

### (Configuration 12)

The electronic circuit according to Configuration 11, wherein
a plurality of the element sections are provided, and
the magnetic flux controller is configured to control the magnetic flux of the space in the loop included in each of the plurality of element sections.

### (Configuration 13)

A computing device, comprising:
the electronic circuit according to Configuration 1; and
the controller configured to supply the excitation signal to the first conductive member.

### (Configuration 14)

The computing device according to Configuration 13, wherein
the first qubit has a first bit frequency,
the second qubit has a second bit frequency,
a resonance characteristic of the first resonator includes a first frequency and a second frequency higher than the first frequency,
at the first frequency, an intensity of the resonance characteristic is 0.1 times a maximum value of the resonance characteristic,
at the second frequency, the intensity of the resonance characteristic is 0.1 times the maximum value,
the first frequency is lower than a sum of the first bit frequency and the second bit frequency,
the second frequency is higher than the sum, and
the excitation signal includes a pulse having a frequency of the sum.

### (Configuration 15)

The computing device according to Configuration 13, wherein
the first qubit has a first bit frequency,
the second qubit has a second bit frequency,
a lower frequency of a full width at half maximum of a resonance characteristic of the first resonator is lower than a sum of the first bit frequency and the second bit frequency,
an upper frequency of the full width at half maximum is higher than the sum, and
the excitation signal includes a pulse having a frequency of the sum.

### (Configuration 16)

The computing device according to Configuration 14 or 15, wherein
the controller is configured to execute a two-qubit gate on the first qubit and the second qubit by supplying the excitation signal to the first conductive member.

### (Configuration 17)

The computing device according to any one of Configurations 13-16, further comprising
a magnetic flux controller configured to control a magnetic flux in a space in the loop.

According to the embodiment, an electronic circuit and a computing device capable of improving performance can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the electronic circuits and computing devices such as qubits, couplers, resonators, conductive members, Josephson junctions, capacitors, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all electronic circuits and all computing devices practicable by an appropriate design modification by one skilled in the art based on the electronic circuits and the computing devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An electronic circuit, comprising:
an element section, including
a first coupler configured to be capacitively coupled with a first qubit and a second qubit, the first coupler including a loop,
a first resonator configured to be inductively coupled with the loop; and
a first conductive member configured to be capacitively coupled with the first resonator, an excitation signal for exciting the first resonator being inputted to the first conductive member.

2. The circuit according to claim 1, wherein
the first qubit has a first bit frequency,
the second qubit has a second bit frequency,
a resonance characteristic of the first resonator includes a first frequency and a second frequency higher than the first frequency,
at the first frequency, an intensity of the resonance characteristic is 0.1 times a maximum value of the resonance characteristic,
at the second frequency, the intensity of the resonance characteristic is 0.1 times the maximum value,
the first frequency is lower than a sum of the first bit frequency and the second bit frequency, and
the second frequency is higher than the sum.

3. The circuit according to claim 1, wherein
the first qubit has a first bit frequency,
the second qubit has a second bit frequency,
a lower frequency of a full width at half maximum of a resonance characteristic of the first resonator is lower than a sum of the first bit frequency and the second bit frequency, and
an upper frequency of the full width at half maximum is higher than the sum.

4. The circuit according to claim 2, wherein
the first qubit has a first state and a second state different from the first state,
the first bit frequency is a frequency corresponding to a difference between a first energy in the first state and a second energy in the second state,
the second qubit has a third state and a fourth state different from the third state, and
the second bit frequency is a frequency corresponding to a difference between a third energy in the third state and a fourth energy in the fourth state.

5. An electronic circuit according to claim 1, further comprising:
a first base including a first face; and
a second base including a second face,
at least a part of the second face facing at least a part of the first face,
the first coupler and the first resonator being provided at the first face,
the first conductive member being provided at the second face.

6. The circuit according to claim 1, further comprising:
a first base including a first face; and
a second base including a second face,
at least a part of the second face facing at least a part of the first face,
the first coupler being provided at the first face, and
the first resonator and the first conductive member being provided at the second face.

7. The circuit according to claim 5, wherein
at least a part of the first resonator does not overlap the loop in a direction from the first base to the second base.

8. The circuit according to claim 1, wherein
the loop includes
a first coupler Josephson junction,
a second coupler Josephson junction,
a third coupler Josephson junction,
a first coupler conductive portion between a part of the first coupler Josephson junction and a part of the third coupler Josephson junction, and
a second coupler conductive portion between a part of the second coupler Josephson junction and another part of the third coupler Josephson junction,
another portion of the first coupler Josephson junction is connected to another part of the second coupler Josephson junction,
the first coupler conductive portion is configured to be capacitively coupled with the first qubit, and
the second coupler conductive portion is configured to be capacitively coupled with the second qubit.

9. The circuit according to claim 8, wherein
the element section further includes the first qubit and the second qubit,
the first qubit includes a first bit Josephson junction and a first bit conductive portion,
a part of the first bit conductive portion is connected to the first bit Josephson junction,
another part of the first bit conductive portion is capacitively coupled to the first coupler conductive portion,
the second qubit includes a second bit Josephson junction and a second bit conductive portion,
a part of the second bit conductive portion is connected to the second bit Josephson junction, and
another part of the second bit conductive portion is capacitively coupled to the second coupler conductive portion.

10. The circuit according to claim 2, wherein
the loop includes
a first coupler Josephson junction,
a second coupler Josephson junction,
a third coupler Josephson junction,
a first coupler conductive portion between a part of the first coupler Josephson junction and a part of the third coupler Josephson junction, and
a second coupler conductive portion between a part of the second coupler Josephson junction and another portion of the third coupler Josephson junction,
another part of the first coupler Josephson junction is connected to another part of the second coupler Josephson junction,
the first coupler conductive portion is capacitively coupled with the first qubit,
the second coupler conductive portion is capacitively coupled with the second qubit,
a first coupler resonance frequency of the first coupler resonator including the first coupler Josephson junction and the first coupler conductive portion is higher than the first bit frequency, higher than the second bit frequency, and lower than the sum, and
a second coupler resonance frequency of the second coupler resonator including the second coupler Josephson junction and the second coupler conductive portion is higher than the first bit frequency, higher than the second bit frequency, and lower than the sum.

11. The circuit according to claim 1, further comprising
a magnetic flux controller configured to control a magnetic flux in a space in the loop.

12. The circuit according to claim 11, wherein
a plurality of the element sections are provided, and
the magnetic flux controller is configured to control the magnetic flux of the space in the loop included in each of the plurality of element sections.

13. A computing device, comprising:
the electronic circuit according to claim 1; and
the controller configured to supply the excitation signal to the first conductive member.

14. The device according to claim 13, wherein
the first qubit has a first bit frequency,
the second qubit has a second bit frequency,
a resonance characteristic of the first resonator includes a first frequency and a second frequency higher than the first frequency,
at the first frequency, an intensity of the resonance characteristic is 0.1 times a maximum value of the resonance characteristic,
at the second frequency, the intensity of the resonance characteristic is 0.1 times the maximum value,
the first frequency is lower than a sum of the first bit frequency and the second bit frequency,
the second frequency is higher than the sum, and
the excitation signal includes a pulse having a frequency of the sum.

15. The device according to claim 13, wherein
the first qubit has a first bit frequency,
the second qubit has a second bit frequency,
a lower frequency of a full width at half maximum of a resonance characteristic of the first resonator is lower than a sum of the first bit frequency and the second bit frequency,
an upper frequency of the full width at half maximum is higher than the sum, and
the excitation signal includes a pulse having a frequency of the sum.

16. The device according to claim 14, wherein
the controller is configured to execute a two-qubit gate on the first qubit and the second qubit by supplying the excitation signal to the first conductive member.

17. The device according to claim 13, further comprising
a magnetic flux controller configured to control a magnetic flux in a space in the loop.
